(19) United States
(12) Patent Application Publication
(10) Pub. No.: US 2026/0182307 A1
(43) Pub. Date: Jun. 25, 2026

(54) VACUUM TABLE AND METHOD FOR CLAMPING WARPED SUBSTRATES

(71) Applicant: ASML Netherlands B.V., Veldhoven (NL)

(72) Inventors: Arjen Franciscus Johannes DE MUNCK, Veldhoven (NL); Gijs KRAMER, Nijmegen (NL); Arnoud Gerhard KAMPHUIS, Hardenberg (NL); Arjan GIJSBERTSEN, Vught (NL); Rudolf Cornelis Henricus BROERS, Eindhoven (NL)

(73) Assignee: ASML Netherlands B.V., Veldhoven (NL)

(21) Appl. No.: 19/129,128

(22) PCT Filed: Nov. 7, 2023
(86) PCT No.: PCT/EP2023/080912

§ 371 Date: May 12, 2025

(30) Foreign Application Priority Data
Dec. 13, 2022 (EP) 22213102.1

(51) Int. Cl. H10P 72/78; B25B 11/00; G03F 7/00; H10P 72/76

(52) U.S. Cl. CPC H10P 72/78; B25B 11/005; G03F 7/70725; G03F 7/70733; G03F 7/70783; G03F 7/70916; H10P 72/7612

(57) ABSTRACT

The disclosure provides a vacuum table, comprising: a table having a top surface for supporting a substrate, the top surface being provided with at least two pressure zones, each pressure zone connected to a respective vacuum connector for providing a reduced pressure, at least one of the pressure zones being provided with grooves extending in radial direction across the top surface. Respective pressure zones may comprise corresponding grooves connected to the respective vacuum connector and extending along the top surface, the grooves of each pressure zone at least extending in a circular direction along the top surface. The radial grooves may extend like fingers from a corresponding circular groove. The radial grooves of one pressure zone extend between radial grooves of another pressure zone. A finger may typically have at least one end unconnected to any other groove.

### CROSS-REFERENCE TO RELATED APPLICATION

The application claims priority of EP application 22213102.1 filed on 13 Dec. 2022, and which is incorporated herein in their entirety by reference.

### FIELD

The present invention relates to a vacuum table and method for clamping a substrate. The substrate may be a wafer for a lithographic process. The invention also relates to a lithographic apparatus provided with the vacuum table.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

To avoid movement of a substrate during patterning, the substrate is typically fixed in a certain position during the lithographic process. For instance, the substrate can be clamped by applying a pressure differential, typically by applying a lower pressure on a side of the substrate facing away from the radiation.

JPH01201936A relates to a plate chuck using vacuum for sucking an object to be exposed in an exposure apparatus for a liquid crystal substrate or the like. In the liquid crystal substrate exposure apparatus, the gap between the original plate (mask) and the object to be exposed (substrate or wafer) is maintained with high accuracy, and the pattern of the mask is transferred to the substrate by photolithography. For this reason, the substrate is vacuum-sucked onto a plate chuck having suction grooves.

JPH04159043A relates to a vacuum chuck for holding a workpiece in a machine tool or a vacuum suction method for various conveying devices. The material to be adsorbed 8 is sucked by radial grooves 4 having through holes 3 provided in a lower adsorption plate 1 and vacuum drawing holes 5 provided in an upper adsorption plate 2. The device has radial grooves. By rotating the lower adsorption plate with respect to the upper adsorption plate, it is possible to provide a vacuum to a region that matches the size of the material to be adsorbed.

JPH07231033A relates to an apparatus for holding a plate-shaped substrate, and more particularly to a projection exposure apparatus for manufacturing semiconductor chips, liquid crystal display elements, etc., and is used to hold semiconductor wafers, ceramic plates, etc. On the mounting surface of the wafer holder, a plurality of ring-shaped concave portions (grooves) are formed radially from the center of the holder. After the wafer is mounted on the mounting surface, the inside of these grooves is decompressed by a vacuum decompression source, so that the back surface of the wafer is vacuum-sucked on the mounting surface over almost the entire surface.

In practice, during the many steps of a semiconductor manufacturing process, substrates may become warped. Warped, or warpage, herein refers to the substrate being curved in one way or another. Warpage or curvature herein can be defined as the height difference between a lowest and a highest point of the substrate, typically of the front side or front surface of the substrate. For instance, while being designed as a flat disk, the substrate may become bend, for instance in a slight saddle shape, hat or trumpet shape, or otherwise. Various mechanisms have been identified, one thereof being inherent to the deposition of multiple metallic layers, which at some point in the process may act as a bi-metal and lead to (slight) curvature. Moreover, due to the multiple deposited layers it may become increasingly difficult or even impossible to flatten the substrate using a clamp or tool.

Conventional vacuum tables for holding substrates prove to have a limited tolerance for curvature or warpage of the substrate. If the curvature exceeds a certain threshold, the vacuum will typically leak. Consequently, the substrate will not seal to the vacuum table. As irradiating a substrate is only viable when the substrate is held in the correct position during the lithographic process, this may and typically will result in loss of the substrate, i.e. yield reduction.

### SUMMARY

The present disclosure aims to improve on the conventional systems as described above.

The disclosure provides a vacuum table, comprising:
a table having a top surface for supporting a substrate,
the top surface being provided with at least two pressure zones, each pressure zone connected to a respective vacuum connector for providing a reduced pressure, at least one of the pressure zones being provided with grooves extending like fingers from a corresponding circular groove in radial direction across the top surface.

In an embodiment, each respective pressure zone comprising corresponding grooves connected to the respective vacuum connector and extending along the top surface, the grooves of each pressure zone at least extending in a circular direction along the top surface.

In an embodiment, the radial grooves extend like fingers from a corresponding circular groove.

In an embodiment, the radial grooves of one pressure zone extend between radial grooves of another pressure zone.

In an embodiment, the top surface is provided with at least three pressure zones.

In an embodiment, a first pressure zone is arranged within a first radial distance from a midpoint of the top surface, and a second pressure zone is arranged between said first radial distance and a perimeter of the top surface.

In an embodiment, a third pressure zone is arranged between the second radial distance and the perimeter of the top surface.

In an embodiment, each respective pressure zone comprises at least one opening fluidly connected to the corresponding vacuum connector.

In an embodiment, the grooves of each pressure zone extend within boundaries of the respective pressure zone, said boundaries being selected from the respective first radial distance, the second radial distance, and the perimeter of the top surface.

The grooves may have a depth in the order of 1 mm.

The top surface can be provided with a central opening for allowing a lifting device to extend therethrough.

In an embodiment, the table comprises a control system connectable to the vacuum connectors of respective pressure zones for controlling the pressure in each pressure zone independently of the pressure in any other pressure zone.

The control system may be adapted to control the first reduced pressure independently of the second reduced pressure and/or the third reduced pressure.

The vacuum table may comprise at least one vacuum source for providing a reduced pressure to the vacuum connectors of respective pressure zones.

According to another aspect, the disclosure provides a lithographic apparatus, comprising at least one vacuum table according to any one of claim 1 to 14.

According to yet another aspect, the disclosure provides a method of clamping a substrate to a vacuum table, the method comprising the steps of:
positioning the substrate on a top surface of the vacuum table, the top surface being provided with at least two pressure zones, each pressure zone connected to a respective vacuum connector for providing a reduced pressure, at least one of the pressure zones being provided with grooves extending in radial direction across the top surface;
applying a first reduced pressure to a first pressure zone until a first threshold has been met indicating that the substrate is clamped to the top surface within said first pressure zone;
applying a second reduced pressure to a second pressure zone until a second threshold has been met indicating that the substrate is clamped to the top surface within said second pressure zone.

In an embodiment, the step of applying a first reduced pressure and/or a second reduced pressure comprises reducing a pressure in corresponding first or second grooves extending radially across the top surface of the vacuum table.

The second threshold may be substantially similar to the first threshold.

The method may comprise the step of applying a third reduced pressure to a third pressure zone until a third threshold has been met indicating that the substrate is clamped to the top surface within said third pressure zone.

The first pressure zone may be arranged within a first radial distance from a midpoint of the top surface, the second pressure zone may be arranged between said first radial distance and a perimeter of the top surface, and optionally the third pressure zone is arranged between the second pressure zone and the perimeter of the top surface.

In an embodiment, the method comprises the step of controlling a reduced pressure in each of the at least two pressure zones independently of the pressure in any other pressure zone.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2A depicts a perspective view of a top surface of an embodiment of a vacuum table of the disclosure;

FIG. 2B depicts a perspective view of a top surface of another embodiment of a vacuum table of the disclosure;

FIG. 2C depicts a perspective view of a bottom of the embodiment of FIG. 2A or 2B;

FIG. 3A depicts a perspective view of a top surface of an embodiment of a vacuum table of the disclosure;

FIG. 3B depicts a perspective view of a top surface of another embodiment of a vacuum table of the disclosure;

FIG. 3C depicts a perspective view of a bottom of the embodiment of FIG. 3A or 3B;

FIG. 4A depicts a diagram of an embodiment of a control scheme to control the vacuum table of the disclosure; and

FIG. 4B depicts a diagram of another embodiment of a control scheme to control the vacuum table of the disclosure.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

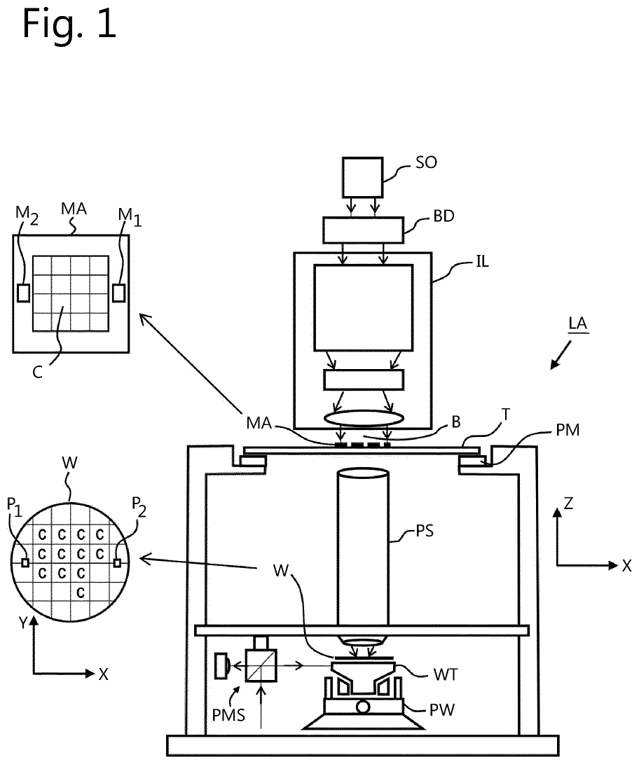

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

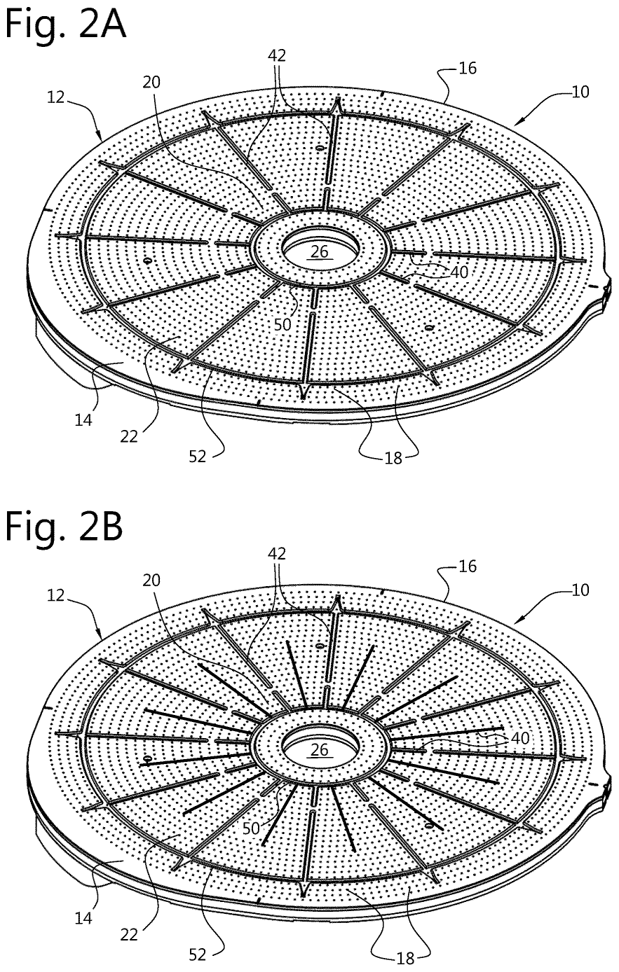

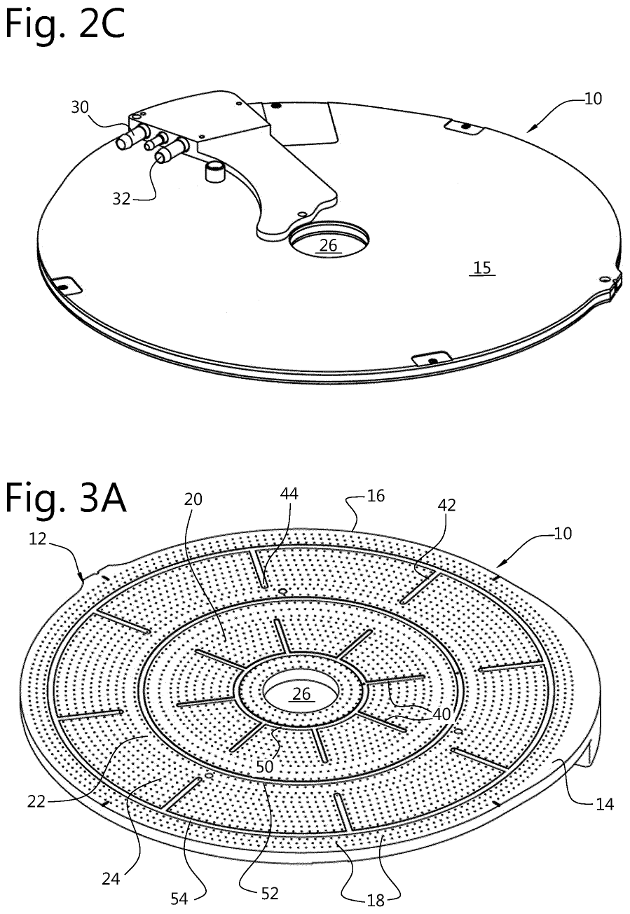

Generally referring to FIG. 2A, the disclosure relates to a vacuum table 10, comprising a table 12 having a top surface 14 for supporting a substrate W. The vacuum table may be included in the substrate table WT (see FIG. 1). The top surface has a perimeter or circumference 16. The top surface may be provided with a number of protrusions 18 for supporting the substrate. The protrusions 18 may be referred to as burls. The burls 18 may have a height in the order of 10 to 250 μm. For an example of the burls and a process of making the protrusions, reference is made to, for instance, patent publication U.S. Pat. No. 7,940,511.

The top surface 14 is provided with at least two pressure zones 20, 22. Each pressure zone is connected to a respective vacuum connector 30, 32 for providing a reduced pressure.

At least one of the pressure zones 20, 22 is provided with fingers 40, 42, i.e. grooves extending in radial direction across the top surface. The fingers or radial grooves are connected to the respective vacuum connector 30, 32 of the corresponding pressure zone. Thus, the radial grooves can spread a pressure as provided via the connectors 30-32, typically a reduced pressure or vacuum, in radial direction across the top surface. Each respective pressure zone may comprise corresponding grooves 50, 52 connected to the respective vacuum connector 30, 32 and extending along the top surface 14. The grooves 50, 52 of each pressure zone may at least extend in a circular direction along the top surface. In embodiment the grooves 50, 52 of each pressure zone may at least partly extend in a circular direction along the top surface. At least partly herein means that the circular grooves may extend along a section of a circle. For instance, the grooves 50, 52 may be comprised of multiple sections, together extending along a circular shape. Multiple circular zones each having a dedicated pressure zone may be formed. The grooves 50, 52 may extend over, for instance, a radius of about 90 degrees. Thus, four or more sections of radial grooves together may constitute a radial groove. The fingers 40, 42 referenced above can be fluidly connected to the grooves extending in circular direction. The fingers may typically have at least one end unconnected to any other groove.

As shown in FIG. 2A, the radial grooves 40, 42 extend like fingers from a corresponding circular groove 50, 52.

As shown in FIG. 2B, at least some of the fingers or radial grooves 40 of one pressure zone 20 may extend between radial grooves 42 of another pressure zone 22. The radial grooves 40 of a particular pressure zone may have different lengths. The latter allows some fingers to extend between the fingers of another pressure zone, while other fingers do not.

The vacuum table may be provided with a central opening 26 for allowing a lifting device to extend therethrough. The vacuum table may be adapted to cooperate with the lifting device (not shown). The lifting device may be adapted to move through the central opening 26 between a lift position, wherein the lifting device lifts the substrate from the top surface 14, and a retracted position wherein the substrate W engages the table 10. The substrate engaging the table 10 herein may mean, for instance, that the substrate is positioned on the top surface 14 (in case of a flat top surface lacking burls 18), or alternatively that the substrate is positioned on top of the protrusions or burls 18.

Generally referring to FIG. 2C, the respective connectors 30, 32 may be arranged on a bottom side 15 of the substrate table 10. The connectors are fluidly connected to the respective pressure zone arranged on the top surface 14. Alternatively, the connectors 30, 32 may be arranged on a side of the substrate table 10.

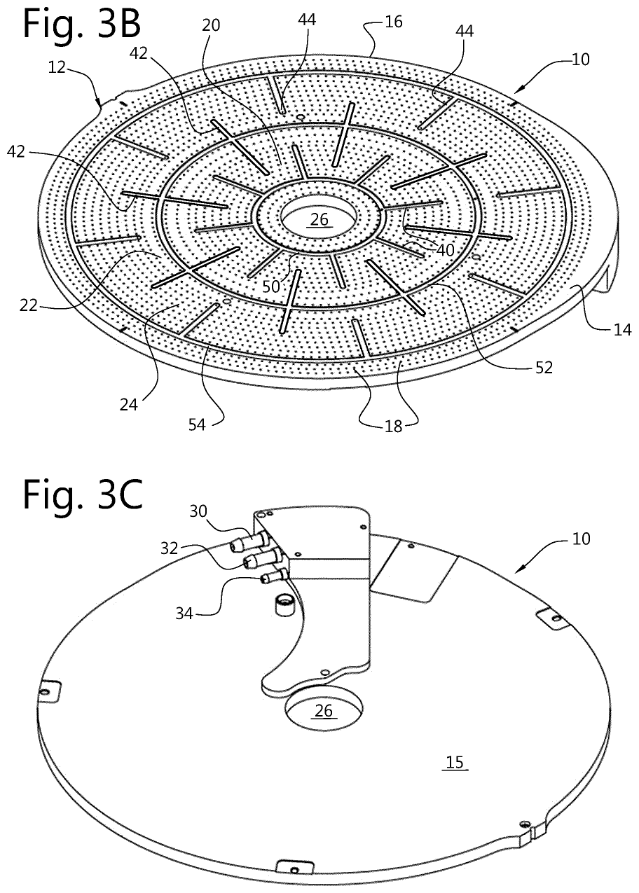

Generally referring to FIGS. 3A to 3C, in an embodiment, the top surface 14 can be provided with at least three pressure zones 20, 22, 24. Herein, a first pressure zone 20 may be arranged within a first radial distance from a midpoint of the top surface 14, and a second pressure zone 22 is arranged between said first radial distance and a second radial distance which exceeds the first radial distance. A third pressure zone 24 can be arranged between the second radial distance and the perimeter 16 of the top surface. Each respective pressure zone can comprise at least one opening fluidly connected to the corresponding vacuum connector 30 to 34.

As exemplified in FIG. 3A, the grooves of each pressure zone may extend within boundaries of the respective pressure zone, said boundaries being selected from the respective first radial distance, the second radial distance, the third radial distance, and the perimeter of the top surface.

As exemplified in FIG. 3B, the radial grooves 40, 42, 44 of one or more pressure zones may extend between fingers of an adjacent pressure zone. Thus, respective pressure zones may at least partially overlap. This provides improved control and increases the range of warpage of substrates that can be handled.

In a practical embodiment, the grooves may have a depth in the order of 0.3 to 2 mm, for instance about 1 mm.

In an embodiment, each of the pressure zones is provided with one or more openings (not shown) connected to the respective connectors 30, 32, 34. The openings are arranged in, or connected to, the grooves of the respective pressure zone. The openings enable to allow gas flow from the opening, and thus from the grooves, to the respective connector of a pressure zone. In a practical embodiment, the one or more openings of each pressure zone are arranged near the inner boundary of the respective pressure zone. The inner boundary herein may mean, in case of a circular top surface 14, the boundary closest to the midpoint or to the central opening 26.

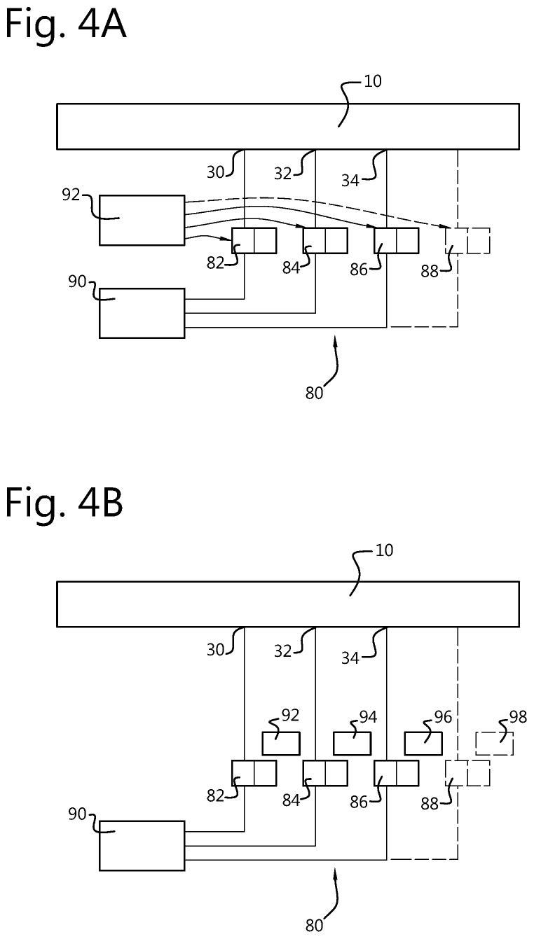

Generally referring to FIGS. 4A and 4B, the vacuum table may comprise, or be connectable to, a control system 80. The control system can be connected between a vacuum source 90 and the vacuum connectors 30, 32, 34 of respective pressure zones. The vacuum source 90 can be connected to the respective connectors using suitable fluid conduits, typically gas lines. The vacuum source 90 may comprise a pump or other means to reduce pressure and/or create a gas flow. The control system 80 may comprise at least two valves 82, 84, 86, 88 for opening or closing a connection between the vacuum source 90 and the respective pressure zone.

The valves may be controllable between an open position and a closed position. In the open position, the respective valve allows fluid flow in the corresponding fluid line. In the closed position, the valve blocks fluid flow in the respective fluid line. The valves may also be controllable to intermediate positions, i.e. positions between a fully open position and a fully closed position. The valves may also be able to gradually open or close, allowing gradual increase or decrease of fluid flow through the respective fluid line, allowing a corresponding pressure drop in the corresponding pressure zone to gradually increase or decrease in relation to the fluid flow.

The control system may comprise one or more controllers 92, 94, 96, 98. For instance, as shown in FIG. 4A, the control system may comprise one controller 92 controlling the respective valves. Alternatively, as shown in FIG. 4B, each valve may be provided with a dedicated controller. In accordance with the disclosure, the fluid flow through the valve connected to each pressure zone, and thus the corresponding pressure in each pressure zone, may be controlled independently of the pressure in any other pressure zone. The control system can be adapted to control a first reduced pressure in the first pressure zone independently of a second reduced pressure in the second pressure zone and/or a third reduced pressure in the third pressure zone.

The vacuum table 10 as described above can be included in the lithographic apparatus LA as exemplified with reference to FIG. 1. The vacuum table 10 may be included in the substrate table WT.

In operation, the vacuum table 10 according to the present disclosure may function as follows. In a typical first step, a substrate can be positioned on the table 10. Positioning on the table herein may mean, for instance, positioning the substrate on the top surface 14 or on top of the burls 18. Positioning the substrate may include various steps. For instance, the substrate may be positioned on the top surface using a substrate handler, such as a robot arm. The substrate handler however may also position the substrate on top of a lift device (not shown) extending through the central opening 26 of the top surface. The top of the lift device may include a suction device for clamping the substrate to the lift device using a reduced pressure. Once the substrate is suitably clamped to the lift device, the lift device may retract through the opening 26 until the substrate engages the top surface 14 of the vacuum table 10.

Please note that a lithographic process typically involves a measurement step measuring, at least, the topography of the substrate. Said topography provides information about the substrate, including warpage and curvature of the substrate. So, once the substrate is positioned on the top surface 14, the system may typically have information available to indicate whether certain parts or sections of the substrate are raised with respect to the top surface, and by how much.

In a next step, the method may involve applying a first reduced pressure to one or more pressure zones until a first threshold has been met indicating that the substrate is clamped to the top surface within said one or more pressure zones.

Subsequently, the method may include applying a second reduced pressure to one or more other pressure zones until a second threshold has been met indicating that the substrate is clamped to the top surface within said one or more other pressure zones.

The selection of which pressure zones to select in the first step, and which to activate subsequently, may differ per substrate. Said selection may typically depend on one or more of curvature, extend of warpage (i.e. maximum difference between highest and lowest point on the substrate), and shape of the curvature (for instance hollow like a bowl, curved like an umbrella, or curled like a taco).

For instance, the method may activate the vacuum first in the pressure zones where the substrate is closest to the top surface. So for a bowl shaped substrate, initially the pressure zone near the middle may be activated, followed by pressure zones more towards the perimeter of the vacuum table. On the other hand, for a substrate which is umbrella shaped, the opposite may be more preferable. So, in this case the outer pressure zone may be activated initially, followed by a pressure zone more towards the middle of the vacuum table once a good vacuum has been established in the outer pressure zone. For a taco shaped substrate, either starting from the middle or starting from the outer pressure zone may be most beneficial, depending on which pressure zone has the best initial contact with the respective substrate. The control system may be operated in a specific way to minimize or prevent damage of the backside of the wafer. For instance when unclamping wafers that are curved like an umbrella, the outer pressure zone could be put to ambient pressure first, before the other pressure zone(s). This prevents normal force on the outer contact points during a natural bulge up of the substrate. In an embodiment the wear resistance of such contact points might be improved by applying e.g. a Diamond-Like Carbon (DLC) coating or similar wear resistant coatings.

The method of the disclosure benefits from the shape of the respective pressure zones, which include fingers extending radially across the top surface of the vacuum table. Herein, the fingers allow the pressure in the respective pressure zone to extend radially.

Even, the fingers of respective pressure zones may partially overlap, as exemplified in FIGS. 2B and 3B. The overlap assists in the gradual flattening of the warped substrate, like rolling the substrate onto the vacuum table one pressure zone to the next.

The method may include applying a first reduced pressure to a first pressure zone until a first threshold has been met indicating that the substrate is clamped to the top surface within said first pressure zone. The method may include applying a second reduced pressure to a second pressure zone until a second threshold has been met indicating that the substrate is clamped to the top surface within said second pressure zone.

The first reduced pressure and/or the second reduced pressure can be applied by reducing a pressure in corresponding first or second grooves of the respective pressure zones extending radially across the top surface of the vacuum table.

The first threshold and the second threshold may be selected from, for instance, a gas flow in a respective pressure line dropping below a set value, and/or a height sensor indicating that a surface of the substrate has dropped below a pre-set margin with respect to the top surface of the vacuum table. The second threshold may be substantially similar to the first threshold.

The method may comprise the steps of applying a third reduced pressure to a third pressure zone until a third threshold has been met indicating that the substrate is clamped to the top surface within said third pressure zone. Similar steps may be repeated for any number of subsequent pressure zones in excess of three.

The control system may control the pressure, typically a reduced pressure, in each of the at least two pressure zones independently of the pressure in any other pressure zone. This allows to optimize the benefits provided by the vacuum table of the disclosure to the shape of a particular substrate. As mentioned above, said shape may range from round (umbrella shape) to hollow (bowl shape) to taco shaped. The control of the pressure zones may be adapted accordingly, for instance starting with a pressure reduction near the middle of the table and proceeding outwards, or vice versa.

The combination of multiple vacuum zones with burls or protrusions provides yet another added benefit. The burls have a limited height. The limited height basically blocks a gas flow between the bottom surface of the substrate and the top surface of the table 10. However, the burls do support the substrate and allow a limited amount of gas flow resulting in and supporting or improving the rolling like motion of the substrate while it flattens over the top surface as the pressure is reduced. In other words, the burls do allow a limited amount of gas flow between the burls, resulting in a pressure reduction and assisted pressure drop. The latter creates an additional pneumatic force or torque on the substrate, further increasing the warpage that can be handled.

Tests and simulations have indicated that the vacuum table according to the present disclosure can extend the range of warpage of a substrate that can be corrected. Substrates herein relate in particular to semiconductor wafers. Such substrates typically include round silicon wafers. A wafer may be about 300 mm in diameter, but can have various sizes. Other substrates include substrates made of other types of materials or combinations of material which behave as a semiconductor under operating conditions.

The vacuum table of the present disclosure can correct, for instance, warpage of a 300 mm diameter semiconductor substrate exceeding about 500 μm, for instance exceeding about 600 μm, for instance exceeding about 700 μm, for instance exceeding about 800 μm, for instance exceeding about 900 μm, or exceeding 1 mm. Warpage up to 2 mm can be corrected using the vacuum table of the disclosure. The vacuum table of the present disclosure can correct, for instance, warpage of a semiconductor substrate exceeding about 1100 μm, for instance exceeding about 1200 μm, for instance exceeding about 1300 μm, for instance exceeding about 1400 μm, for instance exceeding about 1500 μm, for instance exceeding about 1600 μm, for instance exceeding about 1700 μm, for instance exceeding about 1800 μm, for instance exceeding about 1900 μm, for instance exceeding about 2000 μm. The referenced maximum warpage or height differential can be corrected for, at least, a silicon based substrate. The substrate may include multiple deposited layers of metallic and/or semiconducting material to form, for instance, a microchip, a memory element, etc. With respect to conventional vacuum tables suitable for semiconductor manufacturing processes, this is a significant improvement of the amount of warpage that can be handled. For a 300 mm semiconductor wafer, conventional vacuum tables are typically unsuitable for any type of warpage exceeding 300 to 400 μm.

In a practical embodiment, the (gas) flow of each vacuum connection may be in the range of about 10 nl/min and 30 nl/min (normal liter per minute), for instance about 15 to 20 nl/min. 1 Nl/min herein means 10 liter per minute in normal conditions, which is 10 l/min at 1 bar (absolute). A pressure drop of the table may be below 1.0 bar per vacuum channel.

A pressure differential across the substrate may be in the order of 0.1 to 0.5 bar. The pressure differential across the substrate herein may refer to a difference in gas pressure between a top side of the substrate and a bottom side of the substrate. The gas pressure at the bottom side of the substrate can be controlled, typically reduced, using the various pressure zones of the vacuum table of the present disclosure.

The vacuum table of the disclosure allows dedicated control per pressure zone. This greatly increases the ability to adapt and optimize the functioning of the vacuum table to the warpage of a particular substrate. As mentioned before, not only a relatively wide range of maximum height differential for relatively stiff substrates can be corrected and handled. Also, the types of warpage that can still be handles is extended as the dedicated control of respective pressure zones enables to optimize the clamping for the particular substrate. For instance, the substrate can be virtually be rolled onto the top side of the vacuum table one pressure zone to another, either starting at the perimeter, starting at the center of the table, or starting therein between.

The burls or protrusions 18 may have typical height extending from the top surface 14 of the table 10 up to 250 μm. The burls may have a height in the order of 5 to 200 μm, for instance about 10 to 175 μm.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Many modifications may be made to the invention as described without departing from the scope of the claims set out below. Other aspects of the invention are set-out as in the following numbered clauses.
1. A vacuum table, comprising:
   a table having a top surface for supporting a substrate,
   the top surface being provided with at least two pressure zones, each pressure zone connected to a respective vacuum connector for providing a reduced pressure, at least one of the pressure zones being provided with grooves extending in radial direction across the top surface.
2. The vacuum table of clause 1, each respective pressure zone comprising corresponding grooves connected to the respective vacuum connector and extending along the top surface, the grooves of each pressure zone at least extending in a circular direction along the top surface.
3. The vacuum table of clause 2, the grooves of each pressure zone at least partly extending in a circular direction along the top surface.
4. The vacuum table of one of the previous clauses, wherein the radial grooves extend like fingers from a corresponding circular groove.
5. The vacuum table of one of the previous clauses, wherein the radial grooves of one pressure zone extend between radial grooves of another pressure zone.
6. The vacuum table of one of the previous clauses, the top surface being provided with at least three pressure zones.
7. The vacuum table of one of the previous clauses, wherein a first pressure zone is arranged within a first radial distance from a midpoint of the top surface, and a second pressure zone is arranged between said first radial distance and a perimeter of the top surface.
8. The vacuum table of clause 7, wherein a third pressure zone is arranged between the second radial distance and the perimeter of the top surface.
9. The vacuum table of one of the previous clauses, each respective pressure zone comprising at least one opening fluidly connected to the corresponding vacuum connector.
10. The vacuum table of one of clauses 8 or 9, the grooves of each pressure zone extending within boundaries of the respective pressure zone, said boundaries being selected from the respective first radial distance, the second radial distance, and the perimeter of the top surface.
11. The vacuum table of one of the previous clauses, the grooves having a depth in the order of 1 mm.
12. The vacuum table of one of the previous clauses, the top surface being provided with a central opening for allowing a lifting device to extend therethrough.
13. The vacuum table of one of the previous clauses, comprising a control system connectable to the vacuum connectors of respective pressure zones for controlling the pressure in each pressure zone independently of the pressure in any other pressure zone.
14. The vacuum table of clause 13, the control system being adapted to control the first reduced pressure independently of the second reduced pressure and/or the third reduced pressure.
15. The vacuum table of one of the previous clauses, comprising at least one vacuum source for providing a reduced pressure to the vacuum connectors of respective pressure zones.
16. Lithographic apparatus, comprising at least one vacuum table according to any one of clause 1 to 15.
17. A method of clamping a substrate to a vacuum table, the method comprising the steps of:
   positioning the substrate on a top surface of the vacuum table, the top surface being provided with at least two pressure zones, each pressure zone connected to a respective vacuum connector for providing a reduced pressure, at least one of the pressure zones being provided with grooves extending in radial direction across the top surface;
   applying a first reduced pressure to a first pressure zone until a first threshold has been met indicating that the substrate is clamped to the top surface within said first pressure zone;
   applying a second reduced pressure to a second pressure zone until a second threshold has been met indicating that the substrate is clamped to the top surface within said second pressure zone.
18. The method of clause 17, the step of applying a first reduced pressure and/or a second reduced pressure comprising reducing a pressure in corresponding first or second grooves extending radially across the top surface of the vacuum table.
19. The method of clause 18, the second threshold being substantially similar to the first threshold.
20. The method of one of clauses 17, 18 or 19, comprising the step of:
   applying a third reduced pressure to a third pressure zone until a third threshold has been met indicating that the substrate is clamped to the top surface within said third pressure zone.
21. The method of one of clauses 19 to 20, wherein the first pressure zone is arranged within a first radial distance from a midpoint of the top surface, the second pressure zone is arranged between said first radial distance and a perimeter of the top surface, and optionally the third pressure zone is arranged between the second pressure zone and the perimeter of the top surface.
22. The method of one of clauses 17 to 21, comprising the step of controlling a reduced pressure in each of the at least two pressure zones independently of the pressure in any other pressure zone.

1-15. (canceled)

16. A vacuum table, comprising:
a table having a top surface configure to support a substrate,
the top surface being provided with at least two pressure zones, each pressure zone connected to a respective vacuum connector configure to provide a reduced pressure, at least one of the pressure zones being provided with grooves extending like fingers from a corresponding circular groove in radial direction across the top surface, and wherein at least one of the fingers has at least one end unconnected to any other groove.

17. The vacuum table of claim 16, each respective pressure zone comprising corresponding grooves connected to the respective vacuum connector and extending along the top surface, the grooves of each pressure zone at least extending in a circular direction along the top surface.

18. The vacuum table of claim 17, the grooves of each pressure zone at least partly extending in a circular direction along the top surface.

19. The vacuum table of claim 16, wherein the radial grooves of one pressure zone extend between radial grooves of another pressure zone.

20. The vacuum table of claim 16, the top surface being provided with at least three pressure zones.

21. The vacuum table of claim 16, wherein a first pressure zone is arranged within a first radial distance from a midpoint of the top surface, and a second pressure zone is arranged between the first radial distance and a perimeter of the top surface.

22. The vacuum table of claim 16, each respective pressure zone comprising at least one opening fluidly connected to the corresponding vacuum connector.

23. The vacuum table of claim 16, the grooves having a depth in the order of about 1 mm.

24. The vacuum table of claim 16, the top surface being provided with a central opening for allowing a lifting device to extend therethrough.

25. The vacuum table of claim 16, comprising a control system connectable to the vacuum connectors of respective pressure zones for controlling the pressure in each pressure zone independently of the pressure in any other pressure zone.

26. An exposure apparatus comprising at least one vacuum table of claim 16.

27. A method of clamping a substrate to a vacuum table, the method comprising:
positioning the substrate on a top surface of the vacuum table, the top surface being provided with at least two pressure zones, each pressure zone connected to a respective vacuum connector for providing a reduced pressure, at least one of the pressure zones being provided with grooves extending like fingers from a corresponding circular groove in radial direction across the top surface, and wherein at least one of the fingers has at least one end unconnected to any other groove;
applying a first reduced pressure to a first pressure zone until a first threshold has been met indicating that the substrate is clamped to the top surface within the first pressure zone; and
applying a second reduced pressure to a second pressure zone until a second threshold has been met indicating that the substrate is clamped to the top surface within the second pressure zone.

28. The method of claim 27, wherein the applying the first reduced pressure and/or the second reduced pressure comprising reducing a pressure in corresponding first or second grooves extending radially across the top surface of the vacuum table.

29. The method of claim 27, comprising applying a third reduced pressure to a third pressure zone until a third threshold has been met indicating that the substrate is clamped to the top surface within the third pressure zone.

30. The method of claim 27, comprising controlling a reduced pressure in each of the at least two pressure zones independently of the pressure in any other pressure zone.
